(19) United States
(12) Patent Application Publication
(10) Pub. No.: US 2026/0186808 A1
(43) Pub. Date: Jul. 2, 2026

(54) VIRTUAL DEVELOPMENT ENVIRONMENT GENERATION SYSTEM AND VIRTUAL DEVELOPMENT ENVIRONMENT GENERATION METHOD

(71) Applicant: Panasonic Automotive Systems Co., Ltd., Kanagawa (JP)

(72) Inventors: Naoki IKEMOTO, Osaka (JP); Seiya SUDA, Kanagawa (JP); Shintaro MIIKE, Kanagawa (JP)

(73) Assignee: Panasonic Automotive Systems Co., Ltd., Kanagawa (JP)

(21) Appl. No.: 19/377,358

(22) Filed: Nov. 3, 2025

(30) Foreign Application Priority Data
Dec. 4, 2024 (JP) 2024-211562

(51) Int. Cl. G06F 9/455

(52) U.S. Cl. CPC G06F 9/455

(57) ABSTRACT

Virtual development environment generation system 1 generates a virtual development environment by virtualizing a development environment including physical hardware and a physical device connected to the physical hardware. Virtual development environment generation system includes: data receiver that obtains development environment specification information that is information indicating a specification of the development environment; virtual development environment determiner that determines, based on the development environment specification information, a combination of: virtual hardware generated by virtualizing the physical hardware; and a device model generated by virtualizing the physical device, the combination being included in the virtual development environment; and data transmitter that outputs the virtual development environment including the combination determined.

### CROSS REFERENCE TO RELATED APPLICATION

The present application is based on and claims priority of Japanese Patent Application No. 2024-211562 filed on Dec. 4, 2024.

### FIELD

The present disclosure relates to a virtual development environment generation system and a virtual development environment generation method for generating a virtual development environment by virtualizing a development environment including physical hardware and a physical device.

### BACKGROUND

Patent Literature (PTL) 1 discloses a technique that emulates a physical device in a hardware abstraction layer with high fidelity in order to start software development without waiting for the physical device to be ready.

### CITATION LIST

### Patent Literature

PTL 1: Japanese Unexamined Patent Application Publication No. 2020-71870

### SUMMARY

The system disclosed in the above PTL 1 can be improved upon.

In view of the above, the present disclosure provides a virtual development environment generation system and the like capable of improving upon the above related art.

A virtual development environment generation system according to the present disclosure is a virtual development environment generation system that generates a virtual development environment by virtualizing a development environment that includes physical hardware and a physical device connected to the physical hardware. The virtual development environment generation system includes: an obtainer that obtains development environment specification information that is information indicating a specification of the development environment; a determiner that determines, based on the development environment specification information, a combination of: virtual hardware generated by virtualizing the physical hardware; and a device model generated by virtualizing the physical device, the combination being included in the virtual development environment; and an outputter that outputs the virtual development environment including the combination determined.

A virtual development environment generation method according to the present disclosure is a method for generating a virtual development environment by virtualizing a development environment that includes physical hardware and a physical device connected to the physical hardware. The virtual development environment generation method includes: obtaining development environment specification information that is information indicating a specification of the development environment; determining, based on the development environment specification information, a combination of: virtual hardware generated by virtualizing the physical hardware; and a device model generated by virtualizing the physical device, the combination being included in the virtual development environment; and outputting the virtual development environment including the combination determined.

It should be noted that these general and specific aspects may be implemented using a system, a method, an integrated circuit, a computer program, or a computer-readable recording medium such as a CD-ROM, or any combination of systems, methods, integrated circuits, computer programs, and recording media.

The virtual development environment generation system and the like according to one aspect of the present disclosure is capable of improving upon the above related art.

### BRIEF DESCRIPTION OF DRAWINGS

These and other advantages and features of the present disclosure will become apparent from the following description thereof taken in conjunction with the accompanying drawings that illustrate a specific embodiment of the present disclosure.

FIG. 1 is a block diagram illustrating an example of a virtual development environment generation system according to an embodiment.

FIG. 2 is a flowchart illustrating an example of an operation of the virtual development environment generation system according to the embodiment.

FIG. 3 illustrates an example of development environment specification information.

FIG. 4 illustrates an example of a virtual development environment determined from the development environment specification information illustrated in FIG. 3.

FIG. 5A illustrates an example of a correspondence table in which keyword groups are associated with virtual hardware.

FIG. 5B illustrates an example of a correspondence table in which keyword groups are associated with device models.

FIG. 6 illustrates another example of the development environment specification information.

FIG. 7 illustrates an example of a virtual development environment determined from the development environment specification information illustrated in FIG. 6.

FIG. 8 is a diagram for explaining an example of performance prediction of a development environment.

### DESCRIPTION OF EMBODIMENT

In the technique disclosed in PTL 1, when switching virtual hardware or a device model included in the virtual development environment in accordance with changes in the specifications of the development environment, etc., virtual hardware and a device model must be generated repeatedly until the virtual development environment satisfies the desired requirements. This may lead to a reduction in efficiency of development using the virtual development environment. Hereinafter, description is provided on a virtual development environment generation system and a virtual development environment generation method capable of increasing the efficiency of development using the virtual development environment.

Hereinafter, an embodiment will be specifically described with reference to the drawings.

It should be noted that the embodiment described below shows a general or specific example. The numerical values, shapes, materials, structural elements, the arrangement and connection of the structural elements, steps, the order of steps, etc., illustrated in the following embodiment are mere examples, and therefore do not limit the present disclosure.

### Embodiment

Hereinafter, a virtual development environment generation system according to an embodiment will be described.

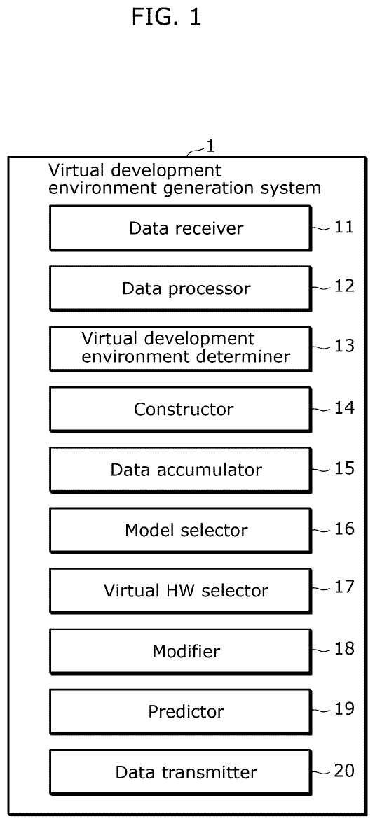

FIG. 1 is a block diagram illustrating an example of virtual development environment generation system 1 according to the embodiment.

Virtual development environment generation system 1 is a system that generates a virtual development environment by virtualizing a development environment including physical hardware and a physical device connected to the physical hardware. The virtual development environment is information that indicates a development environment. The physical hardware is, for example, a system on a chip (SoC) provided to a vehicle. The physical device is, for example, a peripheral device connected to physical hardware, such as a controller area network (CAN) device or a camera provided to a vehicle. A virtual development environment includes a combination of: virtual hardware generated by virtualizing such a physical hardware; and a device model generated by virtualizing such a physical device. The virtual hardware is information that indicates physical hardware, and the device model is information that indicates a physical device.

The virtual hardware simulates, for example, a SoC provided to a latest vehicle model or a SoC provided to an old vehicle model. Examples of the device model include a model with the same output as a physical device under normal conditions, a model with the same response speed as a physical device, a model with the same output as a physical device under heavy load, a model with the same resource consumption as a physical device, and a model with the same computation frequency as a physical device. For example, a device model capable of simulating a physical device with a small number of calculations is called a lightweight model, a device model whose response speed is the same as the response speed of a physical device is called a response speed simulation model, and a device model whose output under normal conditions or under heavy load is the same as the output of a physical device is called an output simulation model.

Virtual development environment generation system 1 includes data receiver 11, data processor 12, virtual development environment determiner 13, constructor 14, data accumulator 15, model selector 16, virtual HW selector 17, modifier 18, predictor 19, and data transmitter 20. Virtual development environment generation system 1 is a computer that includes, for example, a processor (microprocessor), memory, a communication interface (communication circuit, etc.), and a user interface. The memory is read only memory (ROM), random access memory (RAM), or the like which can store programs to be executed by the processor. The user interface includes, for example, a display such as a liquid crystal display (LCD), and an input device such as a keyboard or a touch panel. Data processor 12, virtual development environment determiner 13, constructor 14, model selector 16, virtual HW selector 17, modifier 18, and predictor 19 are realized by a processor or the like that executes a program stored in the memory. Data accumulator 15 may be the same memory as the memory in which programs are stored, or may be a different memory. Data receiver 11 and data transmitter 20 are realized by a communication interface or the like.

For example, virtual development environment generation system 1 may be a computer (device) in a single enclosure or a system including a plurality of computers. When virtual development environment generation system 1 is a system including a plurality of computers, the structural components included in virtual development environment generation system 1 are distributed to the plurality of computers. Moreover, for example, virtual development environment generation system 1 may be a single server or a system including a plurality of servers. When virtual development environment generation system 1 is a system including a plurality of servers, the structural components included in virtual development environment generation system 1 are distributed to the plurality of servers.

Data receiver 11 obtains development environment specification information that is information indicating the specifications of the development environment. Data receiver 11 is an example of an obtainer. Data receiver 11 receives, for example, development documents, such as test specifications, as the development environment specification information. Details of the development environment specification information will be described below.

Data processor 12 processes the data received by data receiver 11 into a format that is easy to use in subsequent processes.

Virtual development environment determiner 13 determines, based on the development environment specification information, a combination of: virtual hardware generated by virtualizing physical hardware; and a device model generated by virtualizing a physical device. The combination is included in a virtual development environment. Virtual development environment determiner 13 is an example of a determiner. The details of an operation of virtual development environment determiner 13 will be described below.

Constructor 14 constructs virtual hardware or a device model that satisfies the requirements for the determined virtual development environment. The details of an operation of constructor 14 will be described below.

Data accumulator 15 stores the data received by data receiver 11, as well as various existing virtual hardware and existing device models. The existing virtual hardware and existing device models may be constructed by constructor 14 or may be constructed in advance.

Model selector 16 selects the device model determined by virtual development environment determiner 13 from among the existing device models stored in data accumulator 15.

Virtual HW selector 17 selects the virtual hardware determined by virtual development environment determiner 13 from among the existing virtual hardware stored in data accumulator 15.

Modifier 18 modifies the combination of the virtual hardware and the device model determined by virtual development environment determiner 13. The determined combination of the virtual hardware and the device model does not always satisfy the requirements for the virtual development environment, and does not always satisfy the developer requirements. Therefore, virtual development environment generation system 1 may include a function to modify the combination. The details of an operation of modifier 18 will be described below.

Predictor 19 predicts the performance of the same software when executed in a development environment on an actual machine (physical hardware and physical device) by executing software in a virtual development environment including the combination of the virtual hardware and the device model determined by virtual development environment determiner 13. The details of an operation of predictor 19 will be described below.

Data transmitter 20 outputs a virtual development environment including the combination of the virtual hardware and the device model determined by virtual development environment determiner 13. Data transmitter 20 is an example of an outputter. For example, data transmitter 20 transmits the device model selected by model selector 16 and the virtual hardware selected by virtual HW selector 17 to a developer who develops physical hardware and physical device software in a virtual development environment. For example, data transmitter 20 also transmits the address of the virtual development environment to the developer.

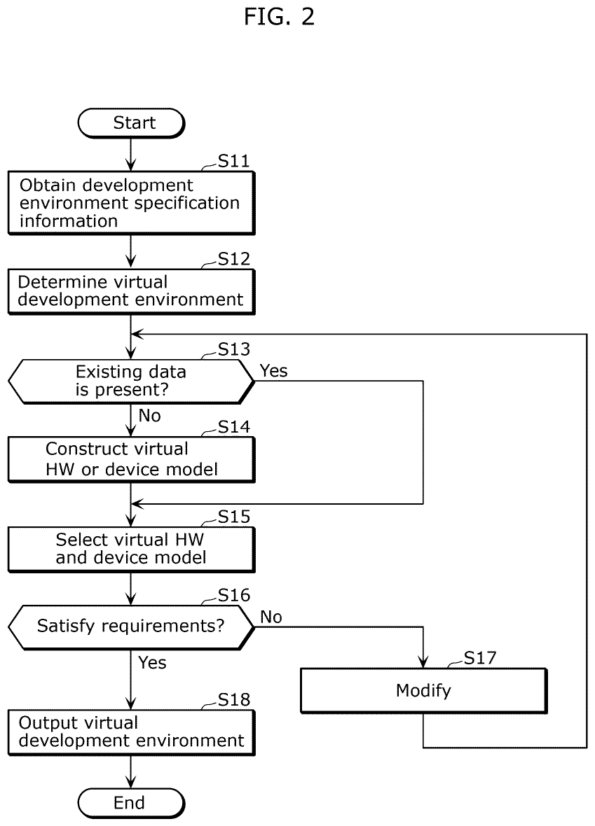

Next, the details of an operation of virtual development environment generation system 1 will be described with reference to FIG. 2.

FIG. 2 is a flowchart illustrating an example of an operation of virtual development environment generation system 1 according to the embodiment.

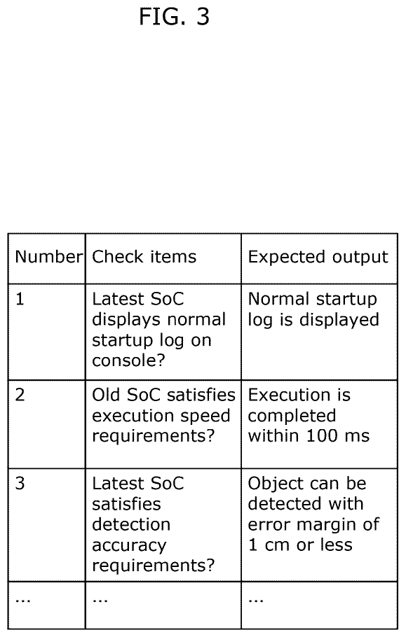

Data receiver 11 obtains development environment specification information (step S11). For example, data receiver 11 receives development environment specification information from the developer. Here, an example of the development environment specification information will be described with reference to FIG. 3.

FIG. 3 illustrates an example of the development environment specification information.

For example, the development environment specification information includes information indicating specification documents of the development environment. For example, as illustrated in FIG. 3, the development environment specification information includes information about specification documents describing the items to be checked in the development environment (check items) and the output expected in the development environment (expected output). Here, the expected output indicates the requirements required for the development environment, and the check items indicate items for checking whether the development environment is capable of outputting the expected output. For example, the specification with number “1” is a specification to check whether the development environment satisfies the requirement that “normal startup log is displayed” by the latest Soc displaying a correct startup log on a console. For example, the specification with number “2” is a specification to check whether the development environment satisfies the requirement that “execution is completed within 100 ms” by the execution speed of an old SoC. For example, the specification with number “3” is a specification to check whether the development environment satisfies the requirement that “an object can be detected with an error margin of 1 cm or less” by the detection speed of an old Soc. The development environment specification information includes target values and threshold values for display contents (processing results), execution speed (processing speed), processing time, accuracy and the like required when software is executed on an actual machine.

The development environment specification information may include information indicating the specifications of the development environment input by the developer. For example, data receiver 11 may obtain the development environment specification information by having the developer input the development environment specifications via a user interface or the like included in virtual development environment generation system 1.

Referring back to the description with reference to FIG. 2, virtual development environment determiner 13 determines a virtual development environment (Step S12). Specifically, virtual development environment determiner 13 determines a combination of virtual hardware and a device model included in the virtual development environment.

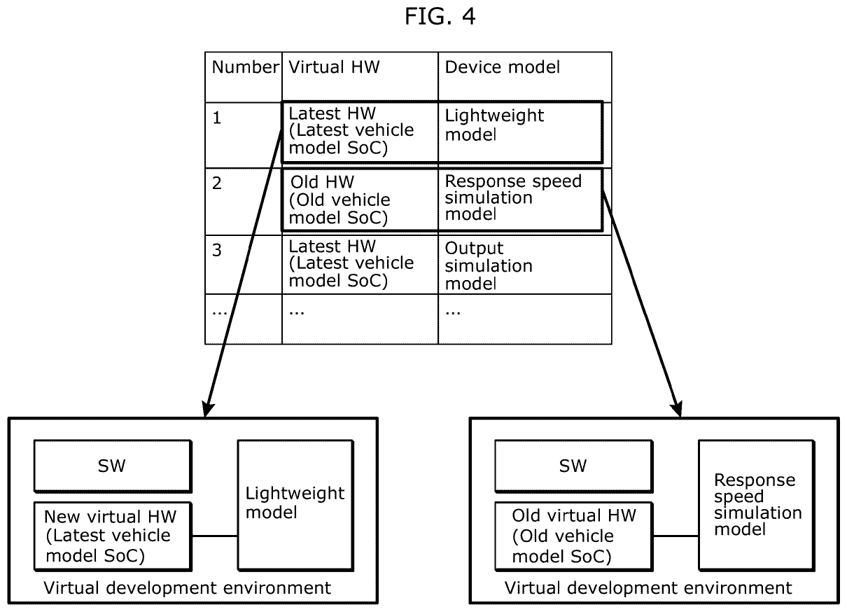

FIG. 4 illustrates an example of a virtual development environment (specifically, a combination of virtual hardware and a device model) determined from the development environment specification information illustrated in FIG. 3.

For example, as illustrated in FIG. 4, for the specification with number “1” indicated by the development environment specification information, a virtual development environment including a combination of virtual hardware generated by virtualizing the latest hardware (e.g., SoC provided to the latest vehicle model) and a lightweight model as a device model is determined. Moreover, for example, as illustrated in FIG. 4, for the specification with number “2” indicated by the development environment specification information, a virtual development environment including a combination of virtual hardware generated by virtualizing old hardware (e.g., SoC provided to an old vehicle model) and a response speed simulation model as a device model is determined.

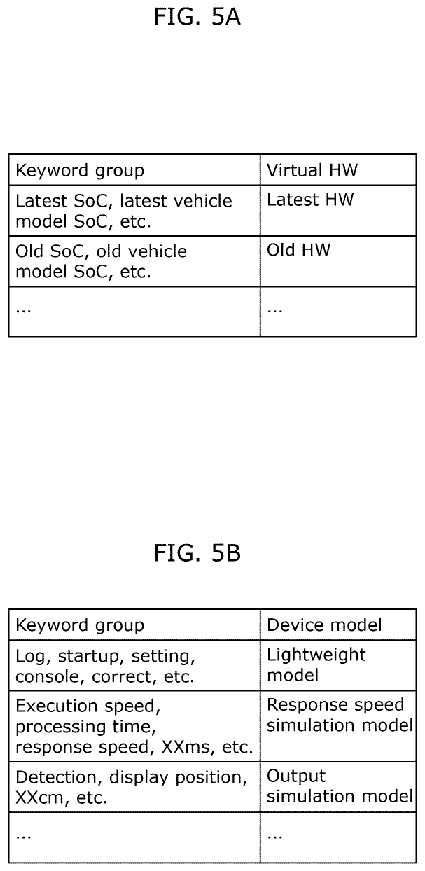

For example, virtual development environment determiner 13 may extract a plurality of keywords included in the development environment specification information and determine a combination of virtual hardware and a device model based on the extracted keywords. For example, virtual development environment determiner 13 checks the extracted keywords against a correspondence table in which keyword groups are associated with virtual hardware and device models that satisfy the requirements for the virtual development environment inferred from the keyword groups. By doing so, the virtual hardware and a device model that are included in the correspondence table and correspond to the extracted keywords may be determined as the combination included in the virtual development environment. Here, examples of the correspondence table will be described with reference to FIG. 5A and FIG. 5B.

FIG. 5A illustrates an example of a correspondence table in which keyword groups are associated with virtual hardware. FIG. 5B illustrates an example of a correspondence table in which keyword groups are associated with device models.

For example, the requirements for a virtual development environment can be inferred in advance from a keyword group that can be described in the specification documents of the development environment, and correspondence tables can be prepared in advance in which the keyword groups are associated with virtual hardware and device models that satisfy the requirements for the virtual development environments.

For example, from a keyword group such as “latest SoC, latest vehicle model Soc” illustrated in FIG. 5A, the requirements for virtual hardware that simulates “latest hardware” can be inferred.

For example, from a keyword group such as “old SoC, old vehicle model Soc” illustrated in FIG. 5A, the requirements for virtual hardware that simulates “old hardware” can be inferred.

For example, from a keyword group such as “log, startup, setting, console, correct” illustrated in FIG. 5B, it is possible to infer the requirements for a virtual development environment such as “software can be executed”, so that a lightweight model can be associated with the keyword group as a device model. For example, for specification with number “1” illustrated in FIG. 3, a plurality of keywords such as “latest SoC, log, console, display, log” are extracted and checked against the correspondence tables illustrated in FIG. 5A and FIG. 5B. By doing so, a combination of virtual hardware that simulates the latest hardware and a lightweight model as a device model is determined.

For example, from a keyword group such as “execution speed, processing time, response speed, XX ms” illustrated in FIG. 5B, the requirements for a virtual development environment, such as “executable in the same execution time as an actual machine” can be inferred. Therefore, a response speed simulation model can be associated with the keyword group as a device model. For example, for the specification with number “2” illustrated in FIG. 3, a plurality of keywords such as “old SoC, execution speed, 100 ms” are extracted and checked against the correspondence tables illustrated in FIG. 5A and FIG. 5B. By doing so, a combination of virtual hardware generated by simulating old hardware and a response speed simulation model as a device model is determined.

For example, from a keyword group such as “detection, display position, XX cm” illustrated in FIG. 5B, it is possible to infer the requirements for a virtual development environment such as “same output as actual machine is possible”. Therefore, an output simulation model can be associated with the keyword group as a device model that satisfies the requirements. For example, for the specification with number “3” illustrated in FIG. 3, a plurality of keywords such as “latest SoC, detection accuracy, 1 cm” are extracted and checked against the correspondence tables illustrated in FIG. 5A and FIG. 5B. By doing so, a combination of virtual hardware generated by simulating the latest hardware and an output simulation model as a device model is determined.

In such a manner, a plurality of keywords related to the requirements for a virtual development environment can be automatically extracted from the development environment specification information, and a combination of virtual hardware and a device model that satisfies the requirements for the virtual development environment can be automatically determined based on the extracted keywords. Therefore, the efficiency of development using the virtual development environment can be increased. Use of the correspondence tables prepared in advance facilitates the determination of a combination of virtual hardware and a device model that satisfies the requirements for the virtual development environment.

A trained model such as generative artificial intelligence (AI) may be used in determining a combination of virtual hardware and a device model. For example, virtual development environment determiner 13 may determine a combination of virtual hardware and a device model included in the virtual development environment by inputting the extracted keywords into a trained model such as a generative AI. The trained model is a model that, when a keyword group is input, outputs information indicating an optimal combination of virtual hardware and a device model satisfying the requirements for the virtual development environment inferred from the keyword group.

Use of the trained model, such as a generative AI, prepared in advance facilitates the determination of a combination of virtual hardware and a device model that satisfies the requirements for the virtual development environment.

When the development environment specification information obtained by data receiver 11 is same as the development environment specification information previously obtained, virtual development environment determiner 13 may determine the previous combination determined based on the development environment specification information previously obtained as the combination included in the current virtual development environment. This allows the previously generated virtual development environment (specifically, combination of virtual hardware and a device model) to be reused, thereby reducing the time required to construct the virtual development environment.

Referring back to the description with reference to FIG. 2, constructor 14 determines whether existing data (specifically, existing virtual hardware or existing device model) that satisfies the requirements for the virtual development environment including the determined combination of the virtual hardware and the device model is stored in data accumulator 15 (Step S13).

When constructor 14 determines that no existing virtual hardware or existing device model that satisfies the requirements for the virtual development environment is stored in data accumulator 15 (No in step S13), constructor 14 constructs virtual hardware or a device model that satisfies the requirements for the virtual development environment, based on the development environment specification information (step S14). For example, by updating the existing virtual hardware or existing device model stored in data accumulator 15, or by generating new virtual hardware or a new device model, virtual hardware or a device model that satisfies the requirements for the virtual development environment may be constructed. Constructor 14 accumulates the constructed virtual hardware or device model in data accumulator 15 as existing virtual hardware or existing device model.

Referring back to the description with reference to FIG. 2, step S15 is performed when constructor 14 determines that existing virtual hardware or an existing device model that satisfies the requirements for the virtual development environment is stored in data accumulator 15 (Yes in step S13) or when virtual hardware or a device model that satisfies the requirements for the virtual development environment is constructed and accumulated in data accumulator 15 as existing virtual hardware or an existing device model. Specifically, virtual HW selector 17 selects the virtual hardware determined by virtual development environment determiner 13 from among the existing virtual hardware stored in data accumulator 15, and model selector 16 selects the device model determined by virtual development environment determiner 13 from among the existing device models stored in data accumulator 15 (Step S15). In other words, the existing virtual hardware and existing device model corresponding to the virtual hardware and the device model determined by virtual development environment determiner 13 are selected.

Next, modifier 18 determines whether the virtual development environment satisfies the requirements for the virtual development environment by executing software in the virtual development environment including the determined combination of the virtual hardware and the device model (specifically, the selected existing virtual hardware and existing device model) (step S16). The determined combination of the virtual hardware and the device model does not always satisfy the requirements for the virtual development environment. Therefore, software is actually executed in the virtual development environment including the combination to determine whether the virtual development environment actually satisfies the requirements for the virtual development environment.

When modifier 18 determines that the virtual development environment does not satisfy the requirements for the virtual development environment (No in step S16), modifier 18 modifies the determined combination (step S17). For example, when the response speed of the determined device model does not satisfy the requirements for the virtual development environment, the response speed of the device model is modified. After the determined combination is modified, the processes from step S13 are performed again. When software is actually executed in the virtual development environment including the determined combination in the above manner and the virtual development environment does not satisfy the requirements, the determined combination can be modified to satisfy the requirements. The modified device model may be accumulated in data accumulator 15 as a new device model.

When modifier 18 determines that the virtual development environment satisfies the requirements for the virtual development environment (Yes in step S16), data transmitter 20 outputs the virtual development environment including the determined combination of the virtual hardware and the device model to the developer (step S18).

Since the determined combination of the virtual hardware and the device model does not always satisfy the developer requirements, modifier 18 may modify the determined combination in response to a request from the developer for modifying the output virtual development environment. The developer may transmit new development specification information reflecting the modification to virtual development environment generation system 1, or may input a modification request via the user interface or the like included in virtual development environment generation system 1. For example, a modification request is received by data receiver 11. With this, it is possible to modify the determined combination to satisfy the developer requirements in response to the request from the developer.

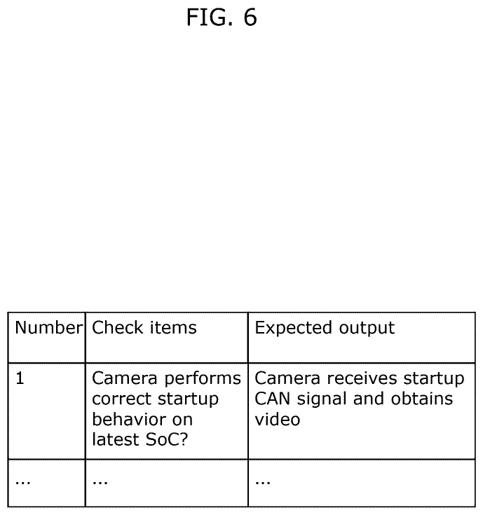

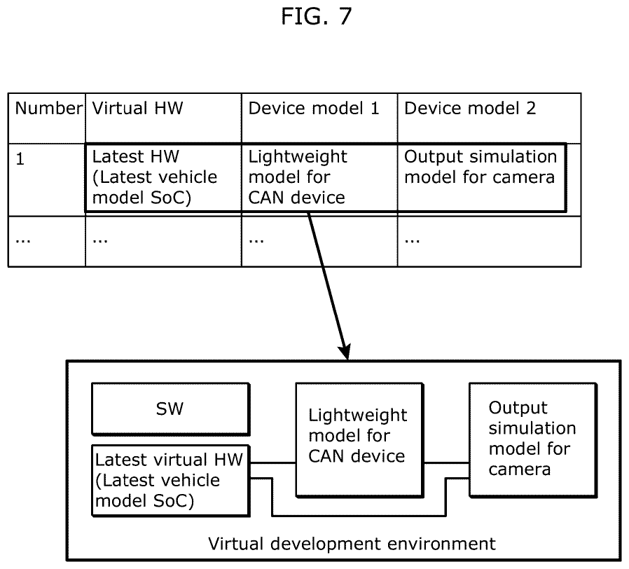

Since there may be more than one devices connected to the hardware provided to the vehicle, the combination determined by virtual development environment determiner 13 may be a combination of a single item of virtual hardware and two or more device models. This will be described with reference to FIG. 6 and FIG. 7.

FIG. 6 illustrates another example of the development environment specification information. FIG. 7 illustrates an example of a virtual development environment determined from the development environment specification information illustrated in FIG. 6.

For example, as illustrated in FIG. 6, the specification with number “1” is a specification to check whether the development environment satisfies the requirement that “the camera receives a startup CAN signal and obtains video” by “whether the camera behaves correctly at startup on the latest SoC”. For this specification, as illustrated in FIG. 7, a virtual development environment including a combination of virtual hardware generated by virtualizing the latest hardware (e.g., SoC provided to the latest vehicle model) a lightweight model for CAN devices as device model 1 and an output simulation model for cameras as device model 2 is determined.

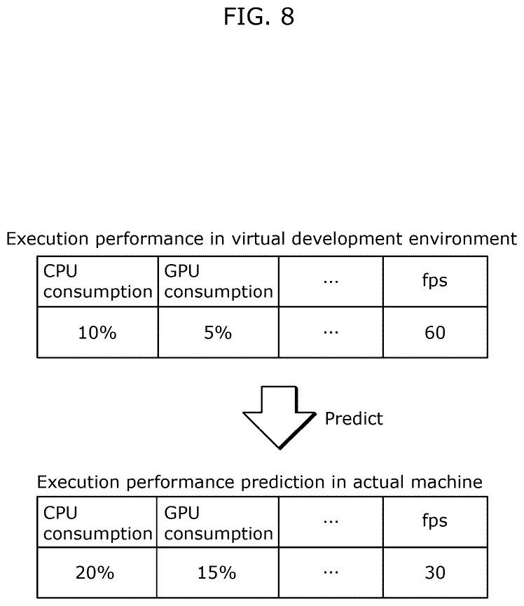

Next, the details of an operation of predictor 19 will be described with reference to FIG. 8.

FIG. 8 illustrates an example of performance prediction of a development environment.

Developers often request to know the execution performance on an actual machine rather than the execution performance in a virtual development environment. In view of the above, predictor 19 predicts the performance of the development environment by executing software in the virtual development environment including the determined combination of the virtual hardware and device model. For example, when the relationship between the execution performance in the virtual development environment and the execution performance on an actual machine is generalized by a relational expression or correspondence table, the execution performance on the actual machine can be predicted from the execution performance in the virtual development environment. For example, when it is known that the CPU consumption on an actual machine will be twice the CPU consumption in the virtual development environment, the CPU consumption on the actual machine will be three times the CPU consumption in the virtual development environment, and the frames per second (fps) on the actual machine will be half the fps in the virtual development environment, as illustrated in FIG. 8, the execution performance on the actual machine can be predicted from the execution performance in the virtual development environment.

As described above, according to virtual development environment generation system 1, a combination of virtual hardware and a device model is automatically determined according to the specifications of the development environment. This reduces the time and effort required to repeatedly generate virtual hardware and device models, leading to an increase in the efficiency of development using a virtual development environment.

### Other Embodiments

The embodiment as an example of the technique according to the present disclosure has been described above. However, the technique according to the present disclosure is not limited to the above example, and can be applied to embodiments in which changes, replacements, additions, omissions, etc. are made as appropriate. For example, variations as described below are included in one embodiment of the present disclosure.

For example, in the embodiment above, an example has been described in which virtual development environment generation system 1 includes constructor 14, modifier 18, and predictor 19. However, virtual development environment generation system 1 does not have to include constructor 14, modifier 18, or predictor 19.

For example, the present disclosure can be realized not only as virtual development environment generation system 1, but also as a virtual development environment generation method that includes steps (processes) performed by structural elements included in virtual development environment generation system 1.

A virtual development environment generation method is a method for generating a virtual development environment by virtualizing a development environment including physical hardware and a physical device connected to the physical hardware. As illustrated in FIG. 2, the virtual development environment generation method includes: obtaining (step S11) development environment specification information that is information indicating a specification of the development environment; determining (step S12), based on the development environment specification information, a combination of: virtual hardware generated by virtualizing the physical hardware; and a device model generated by virtualizing a physical device, the combination being included in the virtual development environment; and outputting (step S18) the virtual development environment including the combination determined.

For example, the present disclosure can be realized as a program for causing a computer (processor) to execute the steps included in the virtual development environment generation method. Moreover, the present disclosure can be realized as a non-transitory computer-readable recording medium such as a CD-ROM on which the program is recorded.

For example, when the present disclosure is realized by a program (software), each step is executed by executing the program using hardware resources such as the CPU, memory, and input and output circuit of the computer. In other words, each step is executed when the CPU obtains data from the memory, the input and output circuit, or the like, performs an operation, and outputs the operation result to the memory, the input and output circuit or the like.

In the embodiment described above, each structural element included in virtual development environment generation system 1 may be configured in the form of a dedicated hardware product or realized by executing a software program suitable for each structural element. Each of the structural elements may be realized by means of a program executing unit, such as a central processing unit (CPU) and a processor, reading and executing the software program recorded on a recording medium such as a hard disk or a semiconductor memory.

Part or all of the functions of virtual development environment generation system 1 according to the embodiment described above is typically realized as a large scale integration (LSI) which is an integrated circuit (IC). They may be individually configured as single chips or may be configured so that part or all of the functions are included in a single chip. Moreover, the integrated circuit is not limited to the LSI, and may be realized by a dedicated circuit or a general-purpose processor. A field programmable gate array (FPGA) which can be programmed after the manufacture of LSI or a reconfigurable processor in which the connection and settings of circuit cells inside the LSI can be reconfigured may be used.

Furthermore, if an integrated circuit technology that replaces an LSI appears due to advances in semiconductor technology or another technology derived from it, it is natural that the technology is used to create an integrated circuit of the structural elements included in virtual development environment generation system 1.

In addition, a form obtained by making various modifications conceivable by those skilled in the art to each embodiment, and a form realized by arbitrarily combining the structural elements and functions in each embodiment without departing from the gist of the present disclosure are also included in the present disclosure.

### Note

The techniques below are disclosed by the embodiment described above.

(Technique 1) A virtual development environment generation system generates a virtual development environment by virtualizing a development environment that includes physical hardware and a physical device connected to the physical hardware. The virtual development environment generation system includes: an obtainer that obtains development environment specification information that is information indicating a specification of the development environment; a determiner that determines, based on the development environment specification information, a combination of: virtual hardware generated by virtualizing the physical hardware; and a device model generated by virtualizing the physical device, the combination being included in the virtual development environment; and an outputter that outputs the virtual development environment including the combination determined.

With this, a combination of virtual hardware and a device model is automatically determined according to the specifications of the development environment. This reduces the time and effort required to repeatedly generate virtual hardware and a device model, leading to an increase in the efficiency of development using a virtual development environment.

(Technique 2) The virtual development environment generation system according to technique 1, in which the determiner extracts a plurality of keywords included in the development environment specification information and determines the combination based on the plurality of keywords extracted.

With this, a plurality of keywords related to the requirements for the virtual development environment can be automatically extracted from the development environment specification information. Based on the extracted keywords, a combination of virtual hardware and a device model that satisfies the requirements for the virtual development environment can be automatically determined. This leads to an increase in the efficiency of development using a virtual development environment.

(Technique 3) The virtual development environment generation system according to technique 2, in which the determiner determines, as the combination included in the virtual development environment, the virtual hardware and the device model that are included in a correspondence table and correspond to the plurality of keywords extracted, by checking the plurality of keywords extracted against the correspondence table, the correspondence table associating a keyword group with the virtual hardware and the device model that satisfy a requirement for the virtual development environment inferred from the keyword group.

With this, use of correspondence tables prepared in advance facilitates the determination of a combination of virtual hardware and a device model that satisfies the requirements for the virtual development environment.

(Technique 4) The virtual development environment generation system according to technique 2, in which, when a keyword group is input, the determiner inputs the plurality of keywords extracted to a trained model that outputs information indicating an optimal combination of: the virtual hardware; and the device model, to determine, as the combination included in the virtual development environment, the optimal combination output from the trained model, the optimal combination satisfying a requirement for the virtual development environment inferred from the keyword group.

With this, use of a trained model such as a generative AI prepared in advance facilitates the determination of a combination of virtual hardware and a device model that satisfies the requirements for the virtual development environment.

(Technique 5) The virtual development environment generation system according to any one of technique 1 to technique 4, further includes: a data accumulator in which existing virtual hardware and an existing device model are stored; and a constructor that: determines whether the existing virtual hardware or the existing device model that satisfies the requirement for a virtual development environment including the combination determined is stored in the data accumulator; and when determining that the existing virtual hardware or the existing device model is not stored in the data accumulator, constructs, based on the development environment specification information, the virtual hardware or the device model that satisfies the requirement for the virtual development environment, and accumulates the virtual hardware or the device model constructed, in the data accumulator as the existing virtual hardware or the existing device model.

For example, when there is no existing virtual hardware or existing device model that satisfies the requirements for the virtual development environment, the virtual development environment cannot be generated. In such a case, virtual hardware or a device model that satisfies the requirements for the virtual development environment can be constructed by updating existing virtual hardware or an existing device model or generating new virtual hardware or a new device model.

(Technique 6) The virtual development environment generation system according to any one of technique 1 to technique 5, further includes: a modifier that modifies the combination determined.

The determined combination of the virtual hardware and the device model does not always satisfy the requirements for the virtual development environment, and does not always satisfy the developer requirements. Therefore, the virtual development environment generation system may include a function to modify the combination.

(Technique 7) The virtual development environment generation system according to technique 6, in which the modifier determines whether the virtual development environment satisfies the requirement for the virtual development environment by executing software in the virtual development environment including the combination determined, and when determining that the virtual development environment does not satisfy the requirement, the modifier modifies the combination determined.

With this, when software is actually executed in a virtual development environment including the determined combination and the virtual development environment does not satisfy the requirements, the determined combination can be modified to satisfy the requirements.

(Technique 8) The virtual development environment generation system according to technique 6 or technique 7, in which the modifier modifies the combination determined, in response to a request from a developer for modifying the virtual development environment output.

With this, it is possible to modify the determined combination to satisfy the developer requirements in response to the request from the developer.

(Technique 9) The virtual development environment generation system according to any one of technique 1 to technique 8, in which the combination is a combination of: a single item of the virtual hardware; and two or more device models each of which is the device model.

In such a manner, a single item of virtual hardware and two or more device models may be combined.

(Technique 10) The virtual development environment generation system according to any one of technique 1 to technique 9, further includes: a predictor that predicts performance of the development environment by executing software in the virtual development environment including the combination determined.

With this, the performance of the actual development environment can be predicted from the performance of the virtual development environment.

(Technique 11) The virtual development environment generation system according to any one of technique 1 to technique 10, wherein, when the development environment specification information obtained by the obtainer is same as development environment specification information previously obtained, the determiner determines, as the combination included in a current virtual development environment, a previous combination determined based on the development environment specification information previously obtained.

With this, it is possible to reuse the previously generated virtual development environment (specifically, combination of virtual hardware and a device model), thereby reducing the time required to construct the virtual development environment.

(Technique 12) The virtual development environment generation system according to any one of technique 1 to technique 11, in which the development environment specification information includes information indicating a specification document of the development environment.

In such a manner, the development environment specification information may be information indicating the specification documents of the development environment.

(Technique 13) The virtual development environment generation system according to any one of technique 1 to technique 12, in which the development environment specification information includes information indicating a specification of the development environment input by a developer.

In such a manner, the development environment specification information may be information indicating the specifications of the development environment input by the developer.

(Technique 14) A virtual development environment generation method for generating a virtual development environment by virtualizing a development environment that includes physical hardware and a physical device connected to the physical hardware, the virtual development environment generation method including: obtaining development environment specification information that is information indicating a specification of the development environment; determining, based on the development environment specification information, a combination of: virtual hardware generated by virtualizing the physical hardware; and a device model generated by virtualizing the physical device, the combination being included in the virtual development environment; and outputting the virtual development environment including the combination determined.

With this, it is possible to provide a virtual development environment generation method capable of increasing the efficiency of development using a virtual development environment.

### Further Information About Technical Background to This Application

The disclosure of the following patent application including specification, drawings, and claims is incorporated herein by reference in its entirety: Japanese Patent Application No. 2024-211562 filed on Dec. 4, 2024.

### INDUSTRIAL APPLICABILITY

The present disclosure is applicable to, for example, a system that virtualizes a software development environment.

1. A virtual development environment generation system that generates a virtual development environment by virtualizing a development environment that includes physical hardware and a physical device connected to the physical hardware, the virtual development environment generation system comprising:
an obtainer that obtains development environment specification information that is information indicating a specification of the development environment;
a determiner that determines, based on the development environment specification information, a combination of: virtual hardware generated by virtualizing the physical hardware; and a device model generated by virtualizing the physical device, the combination being included in the virtual development environment; and
an outputter that outputs the virtual development environment including the combination determined.

2. The virtual development environment generation system according to claim 1,
wherein the determiner extracts a plurality of keywords included in the development environment specification information and determines the combination based on the plurality of keywords extracted.

3. The virtual development environment generation system according to claim 2,
wherein the determiner determines, as the combination included in the virtual development environment, the virtual hardware and the device model that are included in a correspondence table and correspond to the plurality of keywords extracted, by checking the plurality of keywords extracted against the correspondence table, the correspondence table associating a keyword group with the virtual hardware and the device model that satisfies a requirement for the virtual development environment inferred from the keyword group.

4. The virtual development environment generation system according to claim 2,
wherein, when a keyword group is input, the determiner inputs the plurality of keywords extracted to a trained model that outputs information indicating an optimal combination of: the virtual hardware; and the device model, to determine, as the combination included in the virtual development environment, the optimal combination output from the trained model, the optimal combination satisfying a requirement for the virtual development environment inferred from the keyword group.

5. The virtual development environment generation system according to claim 1, further comprising:
a data accumulator in which existing virtual hardware and an existing device model are stored; and
a constructor that:
determines whether the existing virtual hardware or the existing device model that satisfies the requirement for a virtual development environment including the combination determined is stored in the data accumulator; and
when determining that the existing virtual hardware or the existing device model is not stored in the data accumulator, constructs, based on the development environment specification information, the virtual hardware or the device model that satisfies the requirement for the virtual development environment, and accumulates the virtual hardware or the device model constructed, in the data accumulator as the existing virtual hardware or the existing device model.

6. The virtual development environment generation system according to claim 1, further comprising:
a modifier that modifies the combination determined.

7. The virtual development environment generation system according to claim 6,
wherein the modifier determines whether the virtual development environment satisfies the requirement for the virtual development environment by executing software in the virtual development environment including the combination determined, and
when determining that the virtual development environment does not satisfy the requirement, the modifier modifies the combination determined.

8. The virtual development environment generation system according to claim 6,
wherein the modifier modifies the combination determined, in response to a request from a developer for modifying the virtual development environment output.

9. The virtual development environment generation system according to claim 1,
wherein the combination is a combination of: a single item of the virtual hardware; and two or more device models each of which is the device model.

10. The virtual development environment generation system according to claim 1, further comprising:
a predictor that predicts performance of the development environment by executing software in the virtual development environment including the combination determined.

11. The virtual development environment generation system according to claim 1,
wherein, when the development environment specification information obtained by the obtainer is same as development environment specification information previously obtained, the determiner determines, as the combination included in a current virtual development environment, a previous combination determined based on the development environment specification information previously obtained.

12. The virtual development environment generation system according to claim 1,
wherein the development environment specification information includes information indicating a specification document of the development environment.

13. The virtual development environment generation system according to claim 1,
wherein the development environment specification information includes information indicating a specification of the development environment input by a developer.

14. A virtual development environment generation method for generating a virtual development environment by virtualizing a development environment that includes physical hardware and a physical device connected to the physical hardware, the virtual development environment generation method comprising:
obtaining development environment specification information that is information indicating a specification of the development environment;
determining, based on the development environment specification information, a combination of: virtual hardware generated by virtualizing the physical hardware; and a device model generated by virtualizing the physical device, the combination being included in the virtual development environment; and
outputting the virtual development environment including the combination determined.
